(19) United States
(12) Patent Application Publication
(10) Pub. No.: US 2026/0321327 A1
(43) Pub. Date: Oct. 15, 2026

(54) PROGRAM VOLTAGE ADJUSTMENT FOR WEAK DIES IN A MEMORY SUB-SYSTEM

(71) Applicant: Micron Technology, Inc., Boise, ID (US)

(72) Inventors: Peng Zhang, Los Altos, CA (US); Zhenming Zhou, San Jose, CA (US); Jun Wan, San Jose, CA (US); Murong Lang, San Jose, CA (US); Wenyen Chang, San Jose, CA (US); Wei Wang, Fremont, CA (US)

(21) Appl. No.: 19/174,807

(22) Filed: Apr. 9, 2025

(51) Int. Cl. G11C 16/34; G11C 16/08; G11C 16/10

(52) U.S. Cl. CPC G11C 16/3495; G11C 16/08; G11C 16/102

(57) ABSTRACT

A processing device in a memory sub-system identifies a first memory device of a plurality of memory devices that is part of a subset of the plurality of memory devices having lower endurance characteristics than a remainder of the plurality of memory devices, determines whether a program erase cycle count of the first memory device satisfies a threshold criterion, and responsive to determining that the program erase cycle count of the first memory device satisfies the threshold criterion, updates a trim setting for the first memory device, the trim setting specifying an updated program voltage associated with a first set of wordlines of the first memory device.

### TECHNICAL FIELD

Embodiments of the disclosure relate generally to memory sub-systems, and more specifically, relate to program voltage adjustment for weak dies in a memory sub-system.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The present disclosure will be understood more fully from the detailed description given below and from the accompanying drawings of various embodiments of the disclosure.

FIG. 1 illustrates an example computing system that includes a memory sub-system in accordance with some embodiments of the present disclosure.

FIG. 2 is a schematic of portions of an array of memory cells as could be used in a memory of the type described with reference to FIG. 1, in accordance with one or more embodiments of the present disclosure.

FIGS. 3A and FIG. 3B are flow diagrams of example methods of program voltage adjustment for weak dies in a memory sub-system in accordance with some embodiments of the present disclosure.

FIGS. 4A and FIG. 4B are graphs illustrating how a program voltage adjustment for weak dies is made and improves the read window budget in accordance with some embodiments of the present disclosure.

FIG. 5 is a block diagram of an example computer system in which embodiments of the present disclosure may operate.

### DETAILED DESCRIPTION

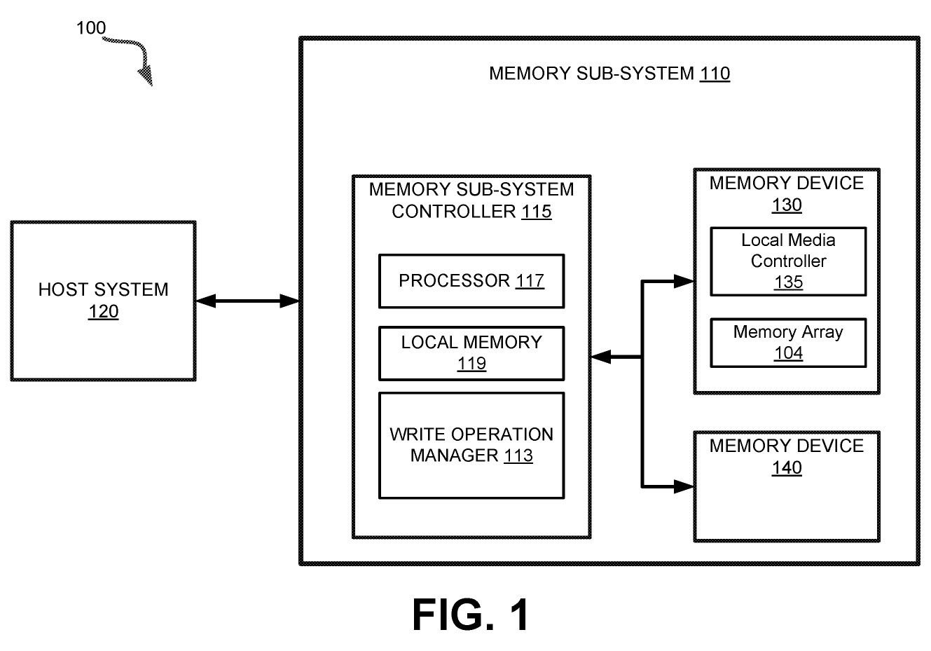

Aspects of the present disclosure are directed to program voltage adjustment for weak dies in a memory sub-system. A memory sub-system can be a storage device, a memory module, or a hybrid of a storage device and memory module. Examples of storage devices and memory modules are described below in conjunction with FIG. 1. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. For example, NAND memory, such as 3D flash NAND memory, offers storage in the form of compact, high-density configurations. A non-volatile memory device is a package of one or more dies, each including one or more planes. For some types of non-volatile memory devices (e.g., NAND memory), each plane includes of a set of physical blocks. Each block includes of a set of pages. Each page includes of a set of memory cells (“cells”). A cell is an electronic circuit that stores information. Depending on the cell type, a cell can store one or more bits of binary information and has various logic states that correlate to the number of bits being stored. The logic states can be represented by binary values, such as “0” and “1”, or combinations of such values.

A memory device can be made up of bits arranged in a two-dimensional or a three-dimensional grid. Memory cells are formed onto a silicon wafer in an array of columns (also hereinafter referred to as bitlines) and rows (also hereinafter referred to as wordlines). A wordline can refer to one or more rows of memory cells of a memory device that are used with one or more bitlines to generate the address of each of the memory cells. The intersection of a bitline and wordline constitutes the address of the memory cell. A block hereinafter refers to a unit of the memory device used to store data and can include a group of memory cells, a wordline group, a wordline, or individual memory cells. One or more blocks can be grouped together to form separate partitions (e.g., planes) of the memory device in order to allow concurrent operations to take place on each plane.

One example of a memory sub-system is a solid-state drive (SSD) that includes one or more non-volatile memory devices (e.g., memory dies) and a memory sub-system controller to manage the non-volatile memory devices. The memory sub-systems can ultimately be sold to a variety of different customers and/or be intended for implementation in a variety of different uses cases. For example, some memory sub-systems can be used in client systems that have relatively light workloads and are not subjected to extreme operating conditions. Other memory sub-systems, however, are intended for mobile applications, or enterprise datacenters, and are likely to face heavier workloads and potentially extreme operating conditions. These different customers and different uses cases may prioritize different features and property and capability characteristics of the memory sub-systems. Accordingly, the memory devices developed for these memory sub-systems, even if based on the same underlying technology, may need to meet different standards for various property and capability characteristics. Certain property and capability characteristics which may be of varying importance include reliability, write performance, data retention, read disturb effect, latent read disturb effect, endurance, or others. In general, however, the majority of these property and capability characteristics can be represented by the read window budget (RWB) present in a given memory device. The read window budget is associated with the read window size (i.e., a size measured in volts, representing the distance, on a voltage scale, between a threshold voltage distribution of memory cells associated with one programming level and a threshold voltage distribution of memory cells associated with a subsequent programming level) on the memory device. The read window budget refers to the cumulative value of the read windows (i.e., the total size of all the read windows of a set of memory cells), and generally is proportional to the property and capability characteristics of the memory device, such that a larger read window budget is indicative of the memory device’s ability to satisfy stricter requirements for the various property and capability characteristics described above.

A certain type of memory device, for example, can include an array of memory cells configured as triple-level cell (TLC) memory (i.e., each cell is configured to store three bits of information). In other examples, the memory cells can be configured as other types of memory, such as single-level cell (SLC) memory, multi-level cell (MLC) memory, quad-level cell (QLC) memory, penta-level cell (PLC) memory, etc. During the manufacturing process, certain memory devices, especially those formed with a higher number of bits per cell, are susceptible to intrinsic variations that may lead to inconsistent operation. As a result, certain issues may arise during operation of the memory device, such as degraded read disturb effects, degraded cycling, erase saturation, higher resistance, etc. These issues may be present throughout an entire memory device (i.e., memory die) or in only portions of the memory device (e.g., on specific wordlines or wordline groups) and may prevent the memory device from meeting the standards for various property and capability characteristics of certain products. Such memory devices may be classified as “weak” or as having “low endurance.” The conventional approach is to either discard such weak memory dies, which dramatically hurts the manufacturing yield, or to use these weak memory dies only in products that have more relaxed standards for the property and capability characteristics.

Certain memory sub-systems attempt to improve the read window budget of the memory devices included therein by adjusting a program voltage applied to the wordlines during a program operation. For example, by decreasing the program voltage used to program the memory cells, the error rate associated with the programming can be reduced, which improves the reliability and read window budget of the memory devices. Decreasing the program voltage, however, leads to longer programming times, which hurts memory sub-system performance and decreases the quality of service provided to host systems utilizing the memory sub-system.

Aspects of the present disclosure address the above and other deficiencies by providing program voltage adjustment for weak dies in a memory sub-system. Certain memory sub-systems include multiple memory devices (i.e., memory dies), some of which may have lower endurance characteristics than others. These memory devices having lower endurance characteristics may be referred to as weak dies. Since these memory sub-systems have some weak dies and some normal dies, a uniform approach to managing program voltages may not be appropriate. Accordingly, a memory sub-system controller can identify those memory devices in the memory sub-system that have the lower endurance characteristics, and selectively adjust the program voltages used for specific wordlines or sets of wordlines on those memory devices. For example, the memory sub-system controller can track a program erase cycle count for those memory devices, and update a trim setting specifying an updated program voltage associated with a given set of wordlines once the program erase cycle count satisfies a threshold criterion (e.g., meets or exceeds a threshold value). In one embodiment, the updated trim setting can represent a lower program voltage that can be used to perform program operations on memory cells associated with certain sets or groups of wordlines that have lower endurance characteristics than other wordlines in the memory device. This one time update can be applicable for the remainder of the life of the memory device.

Advantages of the approach described herein include, but are not limited to, improved property and capability characteristics in the memory sub-system. For example, the negative impact from weak dies on host write performance can be reduced or eliminated and such weak dies can be used in products that have higher standards for the property and capability characteristics (e.g., endurance). In addition, when only certain memory devices in a memory sub-system or certain wordline groups in a memory device are impacted, the overall endurance requirements can still be satisfied by adjusting the respective program voltages. Since the program voltages are not adjusted at the beginning of life of the memory device, program performance (i.e., speed) remains high. Adjusting the program voltage closer to the end of life of the memory device, allows additional endurance to be achieved, thereby increasing the manufacturing yield and allowing more memory dies to be available for products with varying requirements.

FIG. 1 illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., one or more memory device(s) 130), or a combination of such.

A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to different types of memory sub-system 110. FIG. 1 illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller, CXL controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a compute express link (CXL) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access the memory components (e.g., the one or more memory device(s) 130) when the memory sub-system 110 is coupled with the host system 120 by the physical host interface (e.g., PCIe or CXL bus). The physical host interface provides an interface for passing control, address, data, and other signals between the memory sub-system 110 and the host system 120. FIG. 1 illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device(s) 130) include negative-and (NAND) type flash memory and write-in-place memory, such as three-dimensional crosspoint (“3D crosspoint”) memory. A crosspoint array of non-volatile memory can perform bit storage based on a change of bulk resistance, in conjunction with a stackable cross-gridded data access array. Additionally, in contrast to many flash-based memories, crosspoint non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory device(s) 130 can include one or more arrays of memory cells. One type of memory cell, for example, single level cells (SLC) can store one bit per cell. Other types of memory cells, such as multi-level cells (MLCs), triple level cells (TLCs), and quad-level cells (QLCs), can store multiple bits per cell. In some embodiments, each of the memory devices 130 can include one or more arrays of memory cells such as SLCs, MLCs, TLCs, QLCs, or any combination of such. In some embodiments, a particular memory device can include an SLC portion, and an MLC portion, a TLC portion, or a QLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, electrically erasable programmable read-only memory (EEPROM).

A memory sub-system controller 115 (or controller 115 for simplicity) can communicate with the memory device(s) 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processor 117 (e.g., a processing device) configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1 has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory device(s) 130. The memory sub-system controller 115 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address) that are associated with the memory device(s) 130. The memory sub-system controller 115 can further include host interface circuitry to communicate with the host system 120 via the physical host interface. The host interface circuitry can convert the commands received from the host system into command instructions to access the memory device(s) 130 as well as convert responses associated with the memory device(s) 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory device(s) 130.

In some embodiments, the memory device(s) 130 include local media controllers 135 that operate in conjunction with memory sub-system controller 115 to execute operations on one or more memory cells of the memory device(s) 130. An external controller (e.g., memory sub-system controller 115) can externally manage the memory device 130 (e.g., perform media management operations on the memory device(s) 130). In some embodiments, a memory device 130 is a managed memory device, which is a raw memory device (e.g., memory array 104) having control logic (e.g., local controller 135) for media management within the same memory device package. An example of a managed memory device is a managed NAND (MNAND) device. Memory device(s) 130, for example, can each represent a single die having some control logic (e.g., local media controller 135) embodied thereon. In some embodiments, one or more components of memory sub-system 110 can be omitted.

In one embodiment, memory sub-system 110 includes write operation manager 113. In some embodiments, the memory sub-system controller 115 includes at least a portion of the write operation manager 113. In some embodiments, the write operation manager 113 is part of the host system 120, an application, or an operating system. In other embodiments, local media controller 135 includes at least a portion of write operation manager 113 and is configured to perform the functionality described herein. Write operation manager 113 can control write operations performed to the memory dies, such as memory device 130, within memory sub-system 110. In one embodiment, write operation manager 113 can identify a first memory device, such as memory device 130, of a plurality of memory devices in the memory sub-system 110. The first memory device 130 is part of a subset of the plurality of memory devices having lower endurance characteristics than a remainder of the plurality of memory devices (i.e., the first memory device 130 is a “weak die”). Write operation manager 113 can further determine whether a program erase cycle count of the first memory device 130 satisfies a threshold criterion (e.g., meets or exceeds a threshold value), and responsive to determining that the program erase cycle count of the first memory device 130 satisfies the threshold criterion, can update a trim setting for the first memory device 130. In one embodiment, the trim setting specifies an updated program voltage associated with a first set of wordlines of the first memory device 130 (e.g., a set of wordlines having lower endurance characteristics than a reminder of the wordlines of the memory device). Further details with regard to the operations of write operation manager 113 are described below.

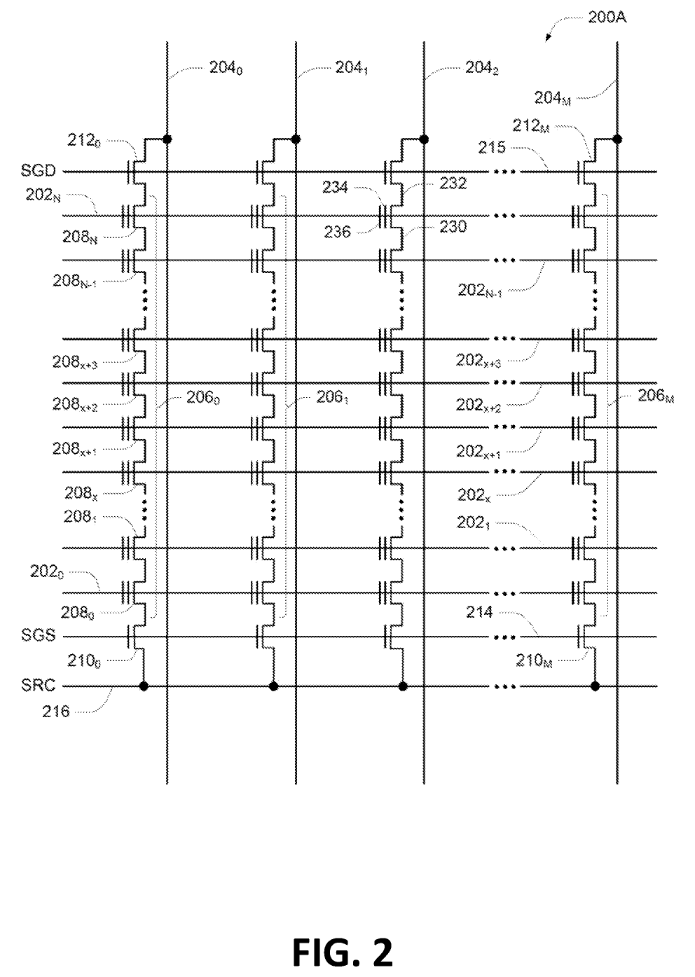

FIG. 2 is a schematics of portions of an array of memory cells 200A, such as a NAND memory array, as could be used in a memory of the type described with reference to FIG. 1 according to an embodiment, e.g., as a portion of the array of memory cells 104. Memory array 200A includes access lines, such as wordlines 202₀ to 202_{N}, and data lines, such as bitlines 204₀ to 204_{M}. The wordlines 202 can be connected to global access lines (e.g., global wordlines), not shown in FIG. 2, in a many-to-one relationship. For some embodiments, memory array 200A can be formed over a semiconductor that, for example, can be conductively doped to have a conductivity type, such as a p-type conductivity, e.g., to form a p-well, or an n-type conductivity, e.g., to form an n-well.

Memory array 200A can be arranged in rows (each corresponding to a wordline 202) and columns (each corresponding to a bitline 204). Each column can include a string of series-connected memory cells (e.g., non-volatile memory cells), such as one of NAND strings 206₀ to 206_{M}. Each NAND string 206 can be connected (e.g., selectively connected) to a common source (SRC) 216 and can include memory cells 208₀to 208_{N}. The memory cells 208 can represent non-volatile memory cells for storage of data. The memory cells 208 of each NAND string 206 can be connected in series between a select gate 210 (e.g., a field-effect transistor), such as one of the select gates 210₀ to 210_{M} (e.g., that can be source select transistors, commonly referred to as select gate source), and a select gate 212 (e.g., a field-effect transistor), such as one of the select gates 212₀to 212_{M} (e.g., that can be drain select transistors, commonly referred to as select gate drain). Select gates 210₀to 210_{M} can be commonly connected to a select line 214, such as a source select line (SGS), and select gates 212₀ to 212_{M} can be commonly connected to a select line 215, such as a drain select line (SGD). Although depicted as traditional field-effect transistors, the select gates 210 and 212 can utilize a structure similar to (e.g., the same as) the memory cells 208. The select gates 210 and 212 can represent a number of select gates connected in series, with each select gate in series configured to receive a same or independent control signal.

A source of each select gate 210 can be connected to common source 216. The drain of each select gate 210 can be connected to a memory cell 208₀ of the corresponding NAND string 206. For example, the drain of select gate 210₀ can be connected to memory cell 208₀ of the corresponding NAND string 206₀. Therefore, each select gate 210 can be configured to selectively connect a corresponding NAND string 206 to the common source 216. A control gate of each select gate 210 can be connected to the select line 214.

The drain of each select gate 212 can be connected to the bitline 204 for the corresponding NAND string 206. For example, the drain of select gate 212₀ can be connected to the bitline 204₀ for the corresponding NAND string 206₀. The source of each select gate 212 can be connected to a memory cell 208_{N} of the corresponding NAND string 206. For example, the source of select gate 212₀ can be connected to memory cell 208_{N} of the corresponding NAND string 206₀. Therefore, each select gate 212 can be configured to selectively connect a corresponding NAND string 206 to the corresponding bitline 204. A control gate of each select gate 212 can be connected to select line 215.

The memory array 200A in FIG. 2 can be a quasi-two-dimensional memory array and can have a generally planar structure, e.g., where the common source 216, NAND strings 206 and bitlines 204 extend in substantially parallel planes. Alternatively, the memory array 200A in FIG. 2 can be a three-dimensional memory array, e.g., where NAND strings 206 can extend substantially perpendicular to a plane containing the common source 216 and to a plane containing the bitlines 204 that can be substantially parallel to the plane containing the common source 216.

Typical construction of memory cells 208 includes a data-storage structure 234 (e.g., a floating gate, charge trap, and the like) that can determine a data state of the memory cell (e.g., through changes in threshold voltage), and a control gate 236, as shown in FIG. 2. The data-storage structure 234 can include both conductive and dielectric structures while the control gate 236 is generally formed of one or more conductive materials. In some cases, memory cells 208 can further have a defined source/drain (e.g., source) 230 and a defined source/drain (e.g., drain) 232. The memory cells 208 have their control gates 236 connected to (and in some cases form) a wordline 202.

A column of the memory cells 208 can be a NAND string 206 or a number of NAND strings 206 selectively connected to a given bitline 204. A row of the memory cells 208 can be memory cells 208 commonly connected to a given wordline 202. A row of memory cells 208 can, but need not, include all the memory cells 208 commonly connected to a given wordline 202. Rows of the memory cells 208 can often be divided into one or more groups of physical pages of memory cells 208, and physical pages of the memory cells 208 often include every other memory cell 208 commonly connected to a given wordline 202. For example, the memory cells 208 commonly connected to wordline 202_{N} and selectively connected to even bitlines 204 (e.g., bitlines 204₀, 204₂, 204₄, etc.) can be one physical page of the memory cells 208 (e.g., even memory cells) while memory cells 208 commonly connected to wordline 202_{N} and selectively connected to odd bitlines 204 (e.g., bitlines 204₁, 204₃, 204₅, etc.) can be another physical page of the memory cells 208 (e.g., odd memory cells).

Although bitlines 204₃-204₅ are not explicitly depicted in FIG. 2, it is apparent from the figure that the bitlines 204 of the array of memory cells 200A can be numbered consecutively from bitline 204₀ to bitline 204_{M}. Other groupings of the memory cells 208 commonly connected to a given wordline 202 can also define a physical page of memory cells 208. For certain memory devices, all memory cells commonly connected to a given wordline can be deemed a physical page of memory cells. The portion of a physical page of memory cells (which, in some embodiments, could still be the entire row) that is read during a single read operation or programmed during a single programming operation (e.g., an upper or lower page of memory cells) can be deemed a logical page of memory cells. A block of memory cells can include those memory cells that are configured to be erased together, such as all memory cells connected to wordlines 202₀-202_{N} (e.g., all NAND strings 206 sharing common wordlines 202). Unless expressly distinguished, a reference to a page of memory cells herein refers to the memory cells of a logical page of memory cells. Although the example of FIG. 2 is discussed in conjunction with NAND flash, the embodiments and concepts described herein are not limited to a particular array architecture or structure, and can include other structures (e.g., SONOS, phase change, ferroelectric, etc.) and other architectures (e.g., AND arrays, NOR arrays, etc.).

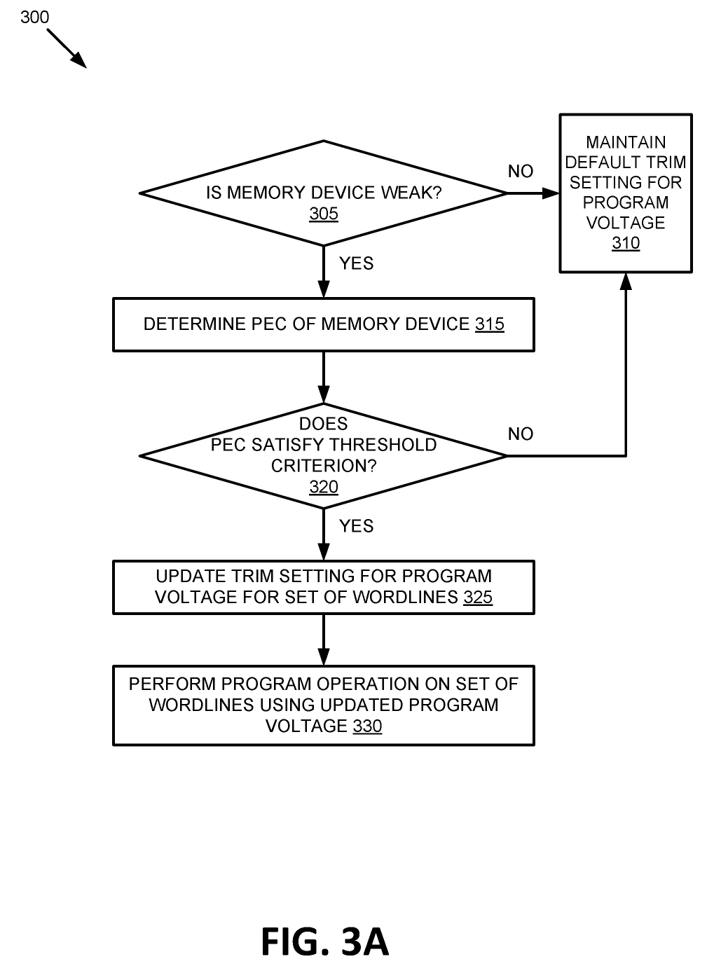

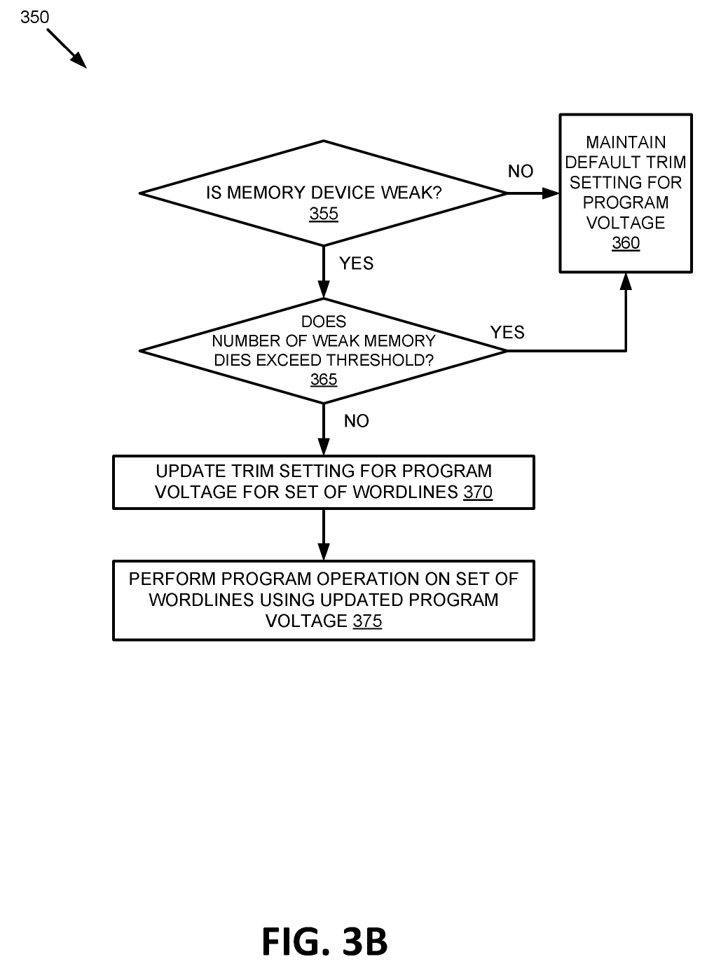

FIG. 3A is a flow diagram of an example method of program voltage adjustment for weak dies in a memory sub-system in accordance with some embodiments of the present disclosure. The method 300 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 300 is performed by write operation manager 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 305, the processing logic (e.g., write operation manager 113 executed by memory sub-system controller 115) identifies a first memory device of a plurality of memory devices that is part of a subset of the plurality of memory devices having lower endurance characteristics than a remainder of the plurality of memory devices. For example, a memory sub-system 110 may include a number of memory devices, some of which have lower endurance characteristics than others. The endurance characteristics can represent a number of program erase cycles (PECs) that the memory device can tolerate before failure, as well as potentially other property and capability characteristics, such as reliability, write performance, data retention, read disturb effect, latent read disturb effect, etc.

In one embodiment the first memory device, such as memory device 130, is predefined as being part of the subset of the plurality of memory devices having lower endurance characteristics than the remainder of the plurality of memory devices based on intrinsic manufacturing characteristics. During the manufacturing process, certain memory devices, especially those formed with a higher number of bits per cell, are susceptible to intrinsic variations that may lead to inconsistent operation. As a result, certain issues may arise during operation of the memory device, such as degraded read disturb effects, degraded cycling, erase saturation, higher resistance, etc. These issues may be present throughout an entire memory device (i.e., memory die) or in only portions of the memory device (e.g., on specific wordlines or wordline groups) and may prevent the memory device from meeting the standards for various property and capability characteristics of certain products. Such memory devices may be classified as “weak” or as having “low endurance” and the memory sub-system controller 115 may maintain an indication (e.g., in firmware metadata) of which memory devices in the memory sub-system have low endurance.

If a given memory device does not have lower endurance characteristics (i.e., is not a weak die), then at operation 310, the processing logic maintains a trim setting representing a default program voltage to be used to perform program operations on the memory device. The trim setting is a firmware configuration setting that represents a program voltage applied to the wordline of the memory device during a program operation. The memory device may be configured with a default program voltage, which can be adjusted in certain scenarios. In this situation, however, the processing logic can maintain the default program voltage.

If the memory device does have lower endurance characteristics (i.e., is a weak die), however, at operation 315, the processing logic determines a program erase cycle count of the first memory device. In one embodiment, the memory sub-system 110 maintains individual counters for each memory device to track the number of program erase cycles that have been performed thereon. The respective counter can be incremented after each program erase cycle is performed.

At operation 320, the processing logic determines whether a program erase cycle count of the first memory device satisfies a threshold criterion. In one embodiment, the processing logic compares the program erase cycle count (i.e., the value of the corresponding counter) to a predefined threshold value. If the program erase cycle count is less than the threshold value, the processing logic can determine that the threshold criterion is not satisfied. Conversely, if the program erase cycle count is greater than or equal to the threshold value, the processing logic can determine that the threshold criterion is satisfied.

If the program erase cycle count of the first memory device does not satisfy the threshold criterion, then at operation 310, the processing logic maintains the trim setting representing a default program voltage to be used to perform program operations on the memory device.

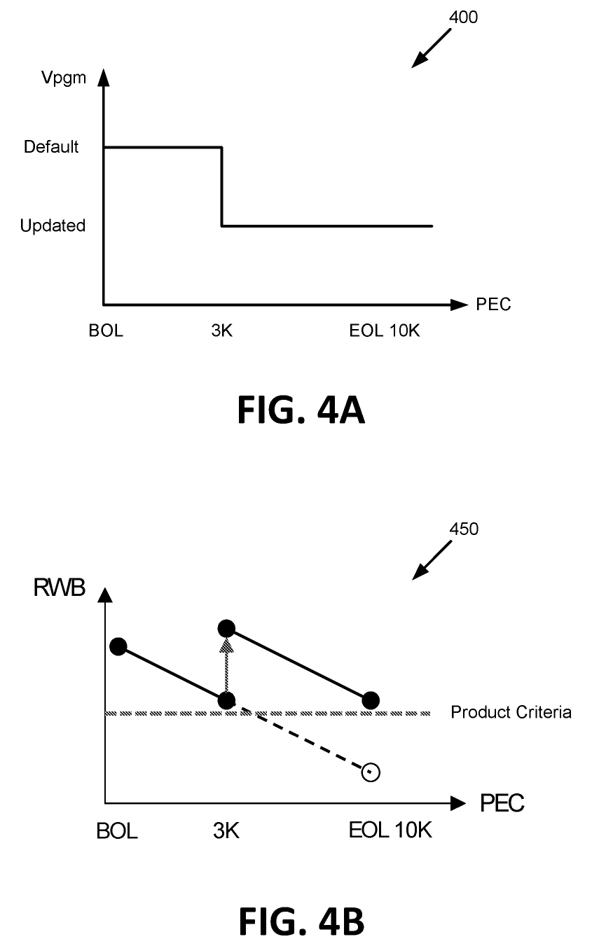

Conversely, responsive to determining that the program erase cycle count of the first memory device satisfies the threshold criterion, at operation 325, the processing logic updates a trim setting for the first memory device, where the trim setting specifies an updated program voltage associated with a first set of wordlines of the first memory device. In one embodiment, the first set of wordlines of the first memory device comprises a subset of a plurality of wordlines of the first memory device, the subset having lower endurance characteristics than a remainder of the plurality of wordlines. For example, if the memory device 130 includes wordlines 202₀ to 202_{N}, as illustrated in FIG. 2, it is possible that only a subset of these wordlines having the lower endurance characteristics. The endurance characteristics can represent a number of program erase cycles (PECs) that the memory device can tolerate before failure, as well as potentially other property and capability characteristics, such as reliability, write performance, data retention, read disturb effect, latent read disturb effect, etc. Accordingly, the processing logic may update the trim setting only for those specific wordlines. In one embodiment, updating the trim setting comprises reducing a default program voltage to the updated program voltage. As illustrated in group 400 of FIG. 4A, the program voltage (Vpgm) may be set initially (i.e., at the beginning of life (BOL) of the memory device, to a default program voltage level. Once the threshold number (e.g., 3K) of program erase cycles (PECs) is reached, the processing logic can reduce the program voltage to the updated program voltage that has a lower magnitude than the default program voltage. This trim setting update can remain in effect for the subset of wordlines until the end of life (EOL) of the memory device.

At operation 330, the processing logic performs a program operation on the first set of wordlines of the first memory device using the updated program voltage. For example, in response to a received request or command (e.g., from host system 120), the memory sub-system controller can initiate a program operation on the first memory device 130. If the program operation is directed to the first set of wordlines (i.e., those wordlines having lower endurance characteristics), the memory sub-system controller can apply the updated program voltage to the selected wordlines. As a result, and as illustrated in graph 450 of FIG. 4B, the read window budget (RWB) may be improved. As illustrated, as the program erase cycle (PEC) count increases from the beginning of life (BOL) of the memory device, the RWB may begin to decline. If allowed to continue to decline, the RWB would potentially fall below certain product criteria thresholds. Accordingly, by updating the program voltage after a threshold number (e.g., 3K) of program erase cycles, the RWB is increased, such that it can remain above the product criteria threshold until the end of life (EOL) of the memory device.

FIG. 3B is a flow diagram of an example method of program voltage adjustment for weak dies in a memory sub-system in accordance with some embodiments of the present disclosure. The method 350 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 350 is performed by write operation manager 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 355, the processing logic (e.g., write operation manager 113 executed by memory sub-system controller 115) identifies a first memory device of a plurality of memory devices that is part of a subset of the plurality of memory devices having lower endurance characteristics than a remainder of the plurality of memory devices. For example, a memory sub-system 110 may include a number of memory devices, some of which have lower endurance characteristics than others. The endurance characteristics can represent a number of program erase cycles (PECs) that the memory device can tolerate before failure, as well as potentially other property and capability characteristics, such as reliability, write performance, data retention, read disturb effect, latent read disturb effect, etc.

In one embodiment, the processing logic can adaptively and dynamically identify a weak memory device during operation of the memory sub-system. For example, the memory sub-system controller 115 may periodically perform a data integrity scan (e.g., a read disturb scan or media scan) of the first memory device 130 to determine a reliability statistic for the memory device. The reliability statistic can include, for example, a total error count, a raw bit error rate (RBER), or some other statistic. Responsive to determining that the reliability statistic exceeds a threshold value, the processing logic may determine that the first memory device 130 is part of the subset of the plurality of memory devices having lower endurance characteristics than the remainder of the plurality of memory devices. This approach is useful to identify a memory device that was not classified as weak during manufacture, but that became weak over its lifetime of use in the memory sub-system.

If a given memory device does not have lower endurance characteristics (i.e., is not a weak die), then at operation 360, the processing logic maintains a trim setting representing a default program voltage to be used to perform program operations on the memory device. The trim setting is a firmware configuration setting that represents a program voltage applied to the wordline of the memory device during a program operation. The memory device may be configured with a default program voltage, which can be adjusted in certain scenarios. In this situation, however, the processing logic can maintain the default program voltage.

If the memory device does have lower endurance characteristics (i.e., is a weak die), however, then at operation 365, the processing logic determines whether a number of memory devices in the subset of the plurality of memory devices having lower endurance characteristics than the remainder of the plurality of memory devices exceeds a threshold number. This threshold number represents a guard band for a maximum number of weak dies that are allowable in a given memory sub-system. For example, if there are 16 memory devices in a memory sub-system, the maximum number of weak dies may be defined as one or two memory devices.

If the number of memory devices in the subset exceeds the threshold number, processing returns to operation 360 and the trim setting representing the default program voltage to be used to perform program operations on the memory device is maintained. When the maximum number of weak dies has been exceeded, the other memory dies that were previously detected as being weak dies can have the adjusted trim setting for the program voltage, since those other memory dies are necessarily weaker than the current die given that the memory dies degrade with additional program erase cycles.

If, however, the number of memory devices in the subset does not exceed the threshold number, at operation 370, the processing logic updates a trim setting for the first memory device, where the trim setting specifies an updated program voltage associated with a first set of wordlines of the first memory device. In one embodiment, the first set of wordlines of the first memory device comprises a subset of a plurality of wordlines of the first memory device, the subset having lower endurance characteristics than a remainder of the plurality of wordlines. For example, if the memory device 130 includes wordlines 202₀ to 202_{N}, as illustrated in FIG. 2, it is possible that only a subset of these wordlines having the lower endurance characteristics. The endurance characteristics can represent a number of program erase cycles (PECs) that the memory device can tolerate before failure, as well as potentially other property and capability characteristics, such as reliability, write performance, data retention, read disturb effect, latent read disturb effect, etc. Accordingly, the processing logic may update the trim setting only for those specific wordlines. In one embodiment, updating the trim setting comprises reducing a default program voltage to the updated program voltage. As illustrated in group 400 of FIG. 4A, the program voltage (Vpgm) may be set initially (i.e., at the beginning of life (BOL) of the memory device, to a default program voltage level. Once the threshold number (e.g., 3K) of program erase cycles (PECs) is reached, the processing logic can reduce the program voltage to the updated program voltage that has a lower magnitude than the default program voltage. This trim setting update can remain in effect for the subset of wordlines until the end of life (EOL) of the memory device.

At operation 375, the processing logic performs a program operation on the first set of wordlines of the first memory device using the updated program voltage. For example, in response to a received request or command (e.g., from host system 120), the memory sub-system controller can initiate a program operation on the first memory device 130. If the program operation is directed to the first set of wordlines (i.e., those wordlines having lower endurance characteristics), the memory sub-system controller can apply the updated program voltage to the selected wordlines. As a result, and as illustrated in graph 450 of FIG. 4B, the read window budget (RWB) may be improved. As illustrated, as the program erase cycle (PEC) count increases from the beginning of life (BOL) of the memory device, the RWB may begin to decline. If allowed to continue to decline, the RWB would potentially fall below certain product criteria thresholds. Accordingly, by updating the program voltage after a threshold number (e.g., 3K) of program erase cycles, the RWB is increased, such that it can remain above the product criteria threshold until the end of life (EOL) of the memory device.

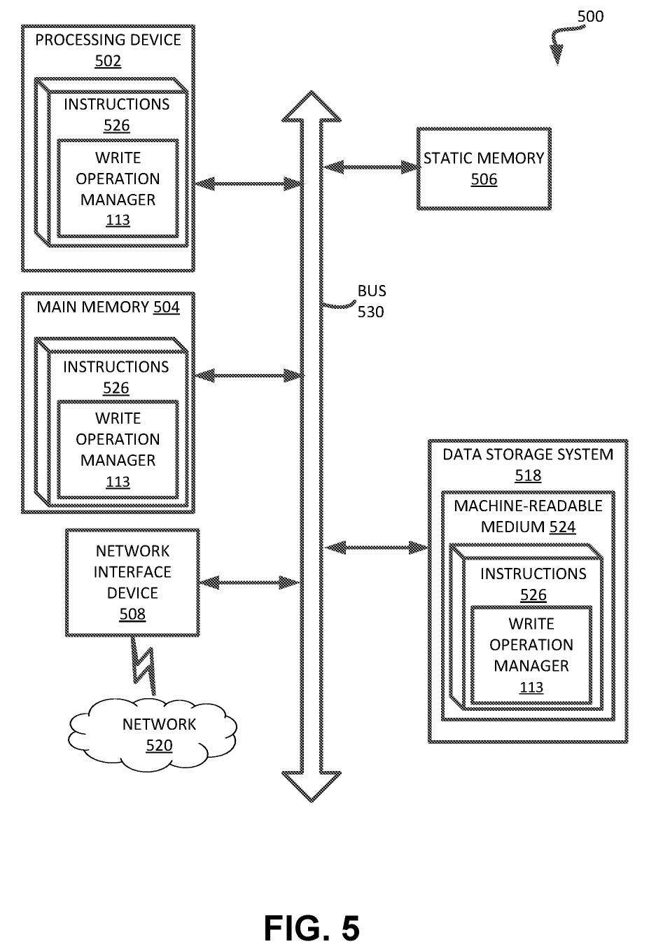

FIG. 5 illustrates an example machine of a computer system 500 within which a set of instructions, for causing the machine to perform any one or more of the methodologies discussed herein, can be executed. In some embodiments, the computer system 500 can correspond to a host system (e.g., the host system 120 of FIG. 1 and configured to perform operations corresponding to write operation manager 113) that includes, is coupled to, or utilizes a memory sub-system (e.g., the memory sub-system 110 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 500 includes a processing device 502, a main memory 504 (e.g., read-only memory (ROM), flash memory, dynamic random access memory (DRAM) such as synchronous DRAM (SDRAM) or Rambus DRAM (RDRAM), etc.), a static memory 506 (e.g., flash memory, static random access memory (SRAM), etc.), and a data storage system 518, which communicate with each other via a bus 530.

Processing device 502 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 502 can also be one or more special-purpose processing devices such as an application specific integrated circuit (ASIC), a field programmable gate array (FPGA), a digital signal processor (DSP), network processor, or the like. The processing device 502 is configured to execute instructions 526 for performing the operations and steps discussed herein. The computer system 500 can further include a network interface device 508 to communicate over the network 520.

The data storage system 518 can include a machine-readable storage medium 524 (also known as a computer-readable medium) on which is stored one or more sets of instructions 526 or software embodying any one or more of the methodologies or functions described herein. The instructions 526 can also reside, completely or at least partially, within the main memory 504 and/or within the processing device 502 during execution thereof by the computer system 500, the main memory 504 and the processing device 502 also constituting machine-readable storage media. The machine-readable storage medium 524, data storage system 518, and/or main memory 504 can correspond to the memory sub-system 110 of FIG. 1.

In one embodiment, the instructions 526 include instructions to implement functionality corresponding to the write operation manager 113 of FIG. 1. While the machine-readable storage medium 524 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A system comprising:
a plurality of memory devices; and
a processing device, operatively coupled with the plurality of memory devices, to perform operations comprising:
identifying a first memory device of the plurality of memory devices that is part of a subset of the plurality of memory devices having lower endurance characteristics than a remainder of the plurality of memory devices;
determining whether a program erase cycle count of the first memory device satisfies a threshold criterion; and
responsive to determining that the program erase cycle count of the first memory device satisfies the threshold criterion, updating a trim setting for the first memory device, the trim setting specifying an updated program voltage associated with a first set of wordlines of the first memory device.

2. The system of claim 1, wherein the processing device is to perform operations further comprising:
determining whether a number of memory devices in the subset of the plurality of memory devices having lower endurance characteristics than the remainder of the plurality of memory devices exceeds a threshold number.

3. The system of claim 1, wherein the first memory device of the plurality of memory devices is predefined as being part of the subset of the plurality of memory devices having lower endurance characteristics than the remainder of the plurality of memory devices based on intrinsic manufacturing characteristics.

4. The system of claim 1, wherein identifying the first memory device of the plurality of memory devices comprises:
performing a data integrity scan of the first memory device to determine a reliability statistic; and
responsive to determining that the reliability statistic exceeds a threshold value, determining that the first memory device is part of the subset of the plurality of memory devices having lower endurance characteristics than the remainder of the plurality of memory devices.

5. The system of claim 1, wherein the processing device is to perform operations further comprising:
performing a program operation on the first set of wordlines of the first memory device using the updated program voltage.

6. The system of claim 1, wherein updating the trim setting for the first memory device comprises reducing a default program voltage to the updated program voltage.

7. The system of claim 1, wherein the first set of wordlines of the first memory device comprises a subset of a plurality of wordlines of the first memory device, the subset having lower endurance characteristics than a remainder of the plurality of wordlines.

8. A method comprising:
identifying a first memory device of a plurality of memory devices that is part of a subset of the plurality of memory devices having lower endurance characteristics than a remainder of the plurality of memory devices;
determining whether a program erase cycle count of the first memory device satisfies a threshold criterion; and
responsive to determining that the program erase cycle count of the first memory device satisfies the threshold criterion, updating a trim setting for the first memory device, the trim setting specifying an updated program voltage associated with a first set of wordlines of the first memory device.

9. The method of claim 8, further comprising:
determining whether a number of memory devices in the subset of the plurality of memory devices having lower endurance characteristics than the remainder of the plurality of memory devices exceeds a threshold number.

10. The method of claim 8, wherein the first memory device of the plurality of memory devices is predefined as being part of the subset of the plurality of memory devices having lower endurance characteristics than the remainder of the plurality of memory devices based on intrinsic manufacturing characteristics.

11. The method of claim 8, wherein identifying the first memory device of the plurality of memory devices comprises:
performing a data integrity scan of the first memory device to determine a reliability statistic; and
responsive to determining that the reliability statistic exceeds a threshold value, determining that the first memory device is part of the subset of the plurality of memory devices having lower endurance characteristics than the remainder of the plurality of memory devices.

12. The method of claim 8, further comprising:
performing a program operation on the first set of wordlines of the first memory device using the updated program voltage.

13. The method of claim 8, wherein updating the trim setting for the first memory device comprises reducing a default program voltage to the updated program voltage.

14. The method of claim 8, wherein the first set of wordlines of the first memory device comprises a subset of a plurality of wordlines of the first memory device, the subset having lower endurance characteristics than a remainder of the plurality of wordlines.

15. A non-transitory computer-readable storage medium storing instructions which, when executed by a processing device, cause the processing device to perform operations comprising:
identifying a first memory device of a plurality of memory devices that is part of a subset of the plurality of memory devices having lower endurance characteristics than a remainder of the plurality of memory devices;
determining whether a program erase cycle count of the first memory device satisfies a threshold criterion; and
responsive to determining that the program erase cycle count of the first memory device satisfies the threshold criterion, updating a trim setting for the first memory device, the trim setting specifying an updated program voltage associated with a first set of wordlines of the first memory device.

16. The non-transitory computer-readable storage medium of claim 15, wherein the first memory device of the plurality of memory devices is predefined as being part of the subset of the plurality of memory devices having lower endurance characteristics than the remainder of the plurality of memory devices based on intrinsic manufacturing characteristics.

17. The non-transitory computer-readable storage medium of claim 15, wherein identifying the first memory device of the plurality of memory devices comprises:
performing a data integrity scan of the first memory device to determine a reliability statistic; and
responsive to determining that the reliability statistic exceeds a threshold value, determining that the first memory device is part of the subset of the plurality of memory devices having lower endurance characteristics than the remainder of the plurality of memory devices.

18. The non-transitory computer-readable storage medium of claim 15, wherein the instructions cause the processing device to perform operations further comprising:
performing a program operation on the first set of wordlines of the first memory device using the updated program voltage.

19. The non-transitory computer-readable storage medium of claim 15, wherein updating the trim setting for the first memory device comprises reducing a default program voltage to the updated program voltage.

20. The non-transitory computer-readable storage medium of claim 15, wherein the first set of wordlines of the first memory device comprises a subset of a plurality of wordlines of the first memory device, the subset having lower endurance characteristics than a remainder of the plurality of wordlines.
